(19) United States
(12) Patent Application Publication
(10) Pub. No.: US 2015/0061042 A1
(43) Pub. Date: Mar. 5, 2015

(54) METAL GATE STRUCTURE AND METHOD OF FABRICATING THE SAME

(71) Applicant: UNITED MICROELECTRONICS CORP., Hsin-Chu City (TW)

(72) Inventors: Tsun-Min Cheng, Changhua County (TW); Nien-Ting Ho, Tainan City (TW); Chien-Hao Chen, Yunlin County (TW); Ching-Yun Chang, Yunlin County (TW); Hsin-Fu Huang, Tainan City (TW); Min-Chuan Tsai, New Taipei City (TW); Chi-Yuan Sun, Yunlin County (TW); Chi-Mao Hsu, Tainan City (TW)

(73) Assignee: UNITED MICROELECTRONICS CORP., Hsin-Chu City (TW)

(21) Appl. No.: 14/016,234

(22) Filed: Sep. 3, 2013

(51) Int. Cl. H01L 29/49; H01L 21/3205; H01L 21/324; H01L 21/285

(52) U.S. Cl. CPC H01L 29/4966; H01L 21/28556; H01L 21/32051; H01L 21/32055; H01L 21/324
USPC 257/412; 438/592

(57) ABSTRACT

A metal gate structure is provided. The metal gate structure includes a semiconductor substrate, a gate dielectric layer, a multi-layered P-type work function layer and a conductive metal layer. The gate dielectric layer is disposed on the semiconductor substrate. The multi-layered P-type work function layer is disposed on the gate dielectric layer, and the multi-layered P-type work function layer includes at least a crystalline P-type work function layer and at least an amorphous P-type work function layer. Furthermore, the conductive metal layer is disposed on the multi-layered P-type work function layer.

### BACKGROUND OF THE INVENTION

1. Field of the Invention

The present invention relates to a metal gate structure and a method of fabricating the same, and more particularly, to a metal gate structure including a multi-layered P-type work function layer and a method of fabricating the same, wherein the multi-layered P-type work function layer includes at least an amorphous P-type work function layer.

2. Description of the Prior Art

Poly-silicon is conventionally used as a gate electrode in semiconductor devices, such as the metal-oxide-semiconductors (MOS). However, with a trend toward scaling down the size of semiconductor devices, the conventional poly-silicon gate has faced problems such as inferior performances due to boron penetration and unavoidable depletion effect, which increases the equivalent thickness of the gate dielectric layer, reduces the gate capacitance, and lowers a driving force of the devices. Therefore, work function metals are used to replace the conventional poly-silicon gate to be the metal gate that is suitable for the high-k gate dielectric layer.

In a complementary metal-oxide semiconductor (CMOS) device, one dual work function metal gate structure is used in an NMOS device and another one is used in a PMOS device. It is well known that compatibility and process control for the dual metal gate structure are more complicated, whereas thickness and composition controls for materials used in the dual metal gate structure method are more precise. In a conventional PMOS device, a P-type work function layer and an N-type work function layer sequentially disposed on the gate dielectric layer accompanying a conductive metal layer can serve as a metal gate, and the metal gate has a work function ranging between 4.8 eV and 5.2 eV. As the N-type work function layer is made of titanium aluminide (TiAl), the aluminum atom in the N-type work function layer may diffuse downward to the P-type work function layer during the high thermal budget processes such as the source/drain activation anneal process, the metal silicide process or BEOL thermal processes, which may affect the work function value of the metal gate, and shift the electrical performances of the PMOS device.

Accordingly, how to improve the structure of the P-type work function layer to avoid the diffusion of the metal atoms from the N-type work function layer and maintain the predetermined performances of the PMOS device is still an important issue in the field.

### SUMMARY OF THE INVENTION

It is therefore one of the objectives of the present invention to provide a metal gate structure including a multi-layered P-type work function layer and a method of fabricating the same, in order to avoid the unexpected occurrence of metal atom diffusion and maintain the predetermined performances of the semiconductor device.

According to one exemplary embodiment of the present invention, a metal gate structure is provided. The metal gate structure includes a semiconductor substrate, a gate dielectric layer, a multi-layered P-type work function layer and a conductive metal layer. The gate dielectric layer is disposed on the semiconductor substrate. The multi-layered P-type work function layer is disposed on the gate dielectric layer, and the multi-layered P-type work function layer includes at least a crystalline P-type work function layer and at least an amorphous P-type work function layer. Furthermore, the conductive metal layer is disposed on the multi-layered P-type work function layer.

According to another exemplary embodiment of the present invention, a method of fabricating a metal gate structure includes the following steps. An inter-layer dielectric (ILD) layer is formed on a substrate, and a gate trench is formed in the ILD layer. Then, a gate a dielectric layer is formed in the gate trench. Subsequently, a multi-layered P-type work function layer is formed on the gate dielectric layer, and a method of forming the multi-layered P-type work function layer at least includes a step of forming an amorphous P-type work function layer after a step of forming a crystalline P-type work function layer. Finally, the conductive metal layer is formed to fill with the gate trench.

The multi-layered P-type work function layer includes an amorphous silicon-containing P-type work function layer disposed on a crystalline P-type work function layer without silicon. The silicon-containing P-type work function layer does not include regular grain boundary; therefore, the amorphous silicon-containing P-type work function layer can be used to prevent the metal atoms from the N-type work function layer or the conductive metal layer from diffusing into the P-type work function layers during the later thermal processes. Accordingly, shifts of the work function value of the metal gate can be avoided, and the predetermined performances of the semiconductor device can be obtained.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 through FIG. 9 illustrate a method of fabricating a metal gate structure according to a preferred exemplary embodiment of the present invention.

FIG. 10 illustrates a metal gate structure according to a preferred exemplary embodiment of the present invention.

### DETAILED DESCRIPTION

To provide a better understanding of the present invention, preferred exemplary embodiments will be described in detail. The preferred exemplary embodiments of the present invention are illustrated in the accompanying drawings with numbered elements.

Please refer to FIG. 1 through FIG. 9, which illustrate a method of fabricating a metal gate structure according to a preferred exemplary embodiment of the present invention. As shown in FIG. 1, a semiconductor substrate 100 is provided, a first region 10 and a second region 20, such as a PMOS region and an NMOS region are defined in the semiconductor substrate 100, and a plurality of shallow trench isolations (STI) 102 are formed in the semiconductor substrate 100 to electrically isolate the two neighboring regions. The semiconductor substrate 100 can be a silicon substrate, an epitaxial silicon substrate, a silicon germanium substrate, a silicon carbide substrate, a silicon-on-insulator (SOI) substrate, or a substrate made of other semiconductor materials, but is not limited thereto. The STI 102 may include dielectric materials such as silicon oxide, or the STI 102 can be replaced by a dielectric structure such as field oxide (FOX). As the STI processes are known to those skilled in the art, the details are omitted herein for brevity.

Subsequently, a first stack structure 104 and a second stack structure 106 are respectively formed in the first region 10 and the second region 20. The method of forming the first stack structure 104 and the second stack structure 106 includes the following steps. At first, an interfacial material layer (not shown) made of dielectric material such as oxides or nitrides is selectively formed on the semiconductor substrate 100, and a gate dielectric material layer (not shown) and a barrier material layer (not shown) are sequentially disposed on the interfacial material layer. Then, a sacrificial layer (not shown) such as a polysilicon layer and a hard mask layer (not shown) are sequentially disposed on the barrier material layer. Afterwards, a pattern transfer process is performed by using a patterned photoresist layer (not shown) as a mask to partially remove the hard mask layer, the sacrificial layer, the barrier material layer, the gate dielectric material layer and the interfacial material layer through single or multiple etching processes to therefore form the first stack structure 104 and the second stack structure 106 on the semiconductor substrate 100. The first stack structure 104 and the second stack structure 106 respectively include an interfacial layer 108, a gate dielectric layer 110, a bottom barrier layer 112, a sacrificial gate 114 and a cap layer 116 disposed sequentially on the semiconductor substrate 100. The interfacial layer 108 could be a dielectric layer having a single layered or multi-layered structure made of silicon oxide (SiO), silicon nitride (SiN) or a combination thereof. The material of the bottom barrier layer 112 may include titanium nitride (TiN). The sacrificial gate 114 may include polysilicon gate. The cap layer 116 could be made of silicon oxide (SiO), silicon nitride (SiN), silicon carbide (SiC), silicon oxynitride (SiON) or a combination thereof.

The present invention can be applied in various semiconductor devices, for example, planar transistors or non-planar transistors such as fin field effect transistor (FinFET), and various metal gate processes including a gate-first process, a high-k first process integrated into the gate-last process, and a high-k last process integrated into the gate-last process. In this exemplary embodiment, the high-k first process integrated into the gate-last process is taken for example, therefore, the formed gate dielectric layer 110 includes a high-k dielectric layer having a “-” shaped cross section. The gate dielectric layer 110 could be made of dielectric materials having a dielectric constant (k value) larger than 4, and the material of the gate dielectric layer 110 may be selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT), lead zirconate titanate (PbZrₓTi₁₋ₓO₃, PZT), barium strontium titanate (BaₓSr₁₋ₓTiO₃, BST) or a combination thereof. The gate dielectric layer 110 can be formed through an atomic layer deposition (ALD) process or a metal-organic chemical vapor deposition (MOCVD) process, but is not limited thereto.

An ion implantation process can be selectively performed to form lightly doped drain (LDD) at two sides of the first stack structure 104/the second stack structure 106. Subsequently, a spacer 120, a source/drain region, a contact etch stop layer (CESL) 124 and an inter-layer dielectric (ILD) layer 126 are formed in sequence. A first lightly doped drain 118A and a first source/drain region 122A having a first conductivity type, such as P-type, are formed in the first region 10, while a second lightly doped drain 118B and a second source/drain region 122B having a second conductivity type, such as N-type, are formed in the second region 20. The CESL 124 can be selectively disposed between the first stack structure 104/the second stack structure 106 and the ILD layer 126, and a material of the CESL 124 may include dielectric materials such as silicon nitride (SiN), nitrogen doped silicon carbide (NDC). Additionally, the CESL 124 can further include a stress. The ILD layer 126 can be made of dielectric materials and be formed through a spin-on-coating (SOC) process, a chemical vapor deposition (CVD) process or other suitable process, and the dielectric materials include low dielectric constant (low-k) material (k value smaller than 3.9), ultra low-k (ULK) material (k value smaller than 2.6), or porous ULK material, but is not limited thereto.

After forming the source/drain region and before forming the CESL 124 and the ILD layer 126, a self-aligned metal silicide (salicide) process can be performed. A metal layer made of materials such as cobalt (Co), titanium (Ti), tantalum (Ta), platinum (Pt), palladium (Pd), molybdenum (Mo), etc. is first formed on the semiconductor substrate 100 to cover the first source/drain region 122A and the second source/drain region 122B. Then, at least one rapid thermal anneal (RTP) process is performed to have the metal layer react with the silicon epitaxial layer of the first source/drain region 122A and the second source/drain region 122B, and a metal silicide layer 123 can be formed on the overall surface of the first source/drain region 122A and the second source/drain region 122B. Finally, the non-reacted metal layer is removed, and a formed metal silicide layer 123 totally covers the first source/drain region 122A and the second source/drain region 122B. It is noted that the timing for performing the self-aligned metal silicide process is not limited to this, it may also be carried out after the subsequent processes for forming the source/drain contact holes in the ILD layer 126 and the source/drain contact holes expose the source/drain regions in the ILD layer 126.

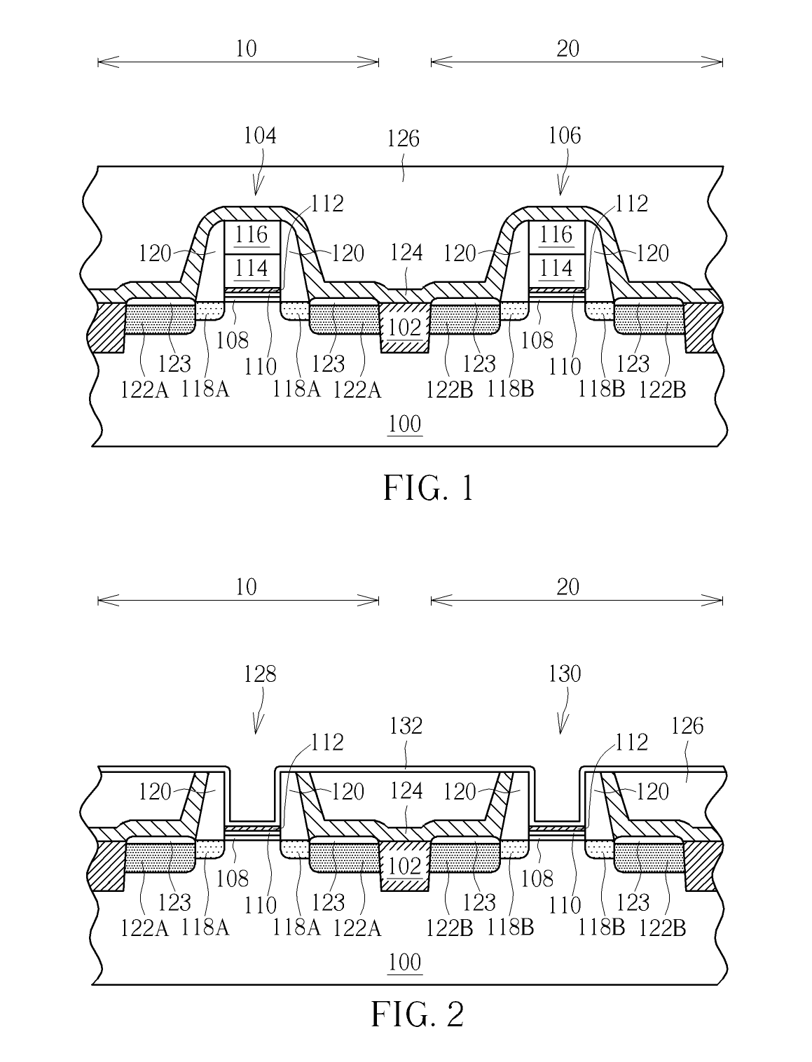

As shown in FIG. 2, a planarization process, such as a chemical mechanical polish (CMP) process or an etching back process, can be performed to sequentially remove a part of the ILD layer 126, a part of the CESL 124, a part of the spacer 120 and the overall cap layer 116, until the sacrificial gate 114 is exposed. Then, the sacrificial gate 114 is removed and the bottom barrier layer 112 is used as a protective layer to respectively form a first gate trench 128 and a second gate trench 130 in the ILD layer 126 in the first region 10 and the second region 20. It is appreciated that, as the gate dielectric layer 110 is covered by the bottom barrier layer 112, the gate dielectric layer 110 may not be etched or removed during the above processes. Afterwards, an etch stop layer 132 is selectively formed to entirely and conformally cover the bottoms and the inner surfaces of the first gate trench 128 and the second gate trench 130. The material of the etch stop layer 132 preferably differs from that of the bottom barrier layer 112. For example, the etch stop layer 132 may include tantalum nitride (TaN), but not limited thereto.

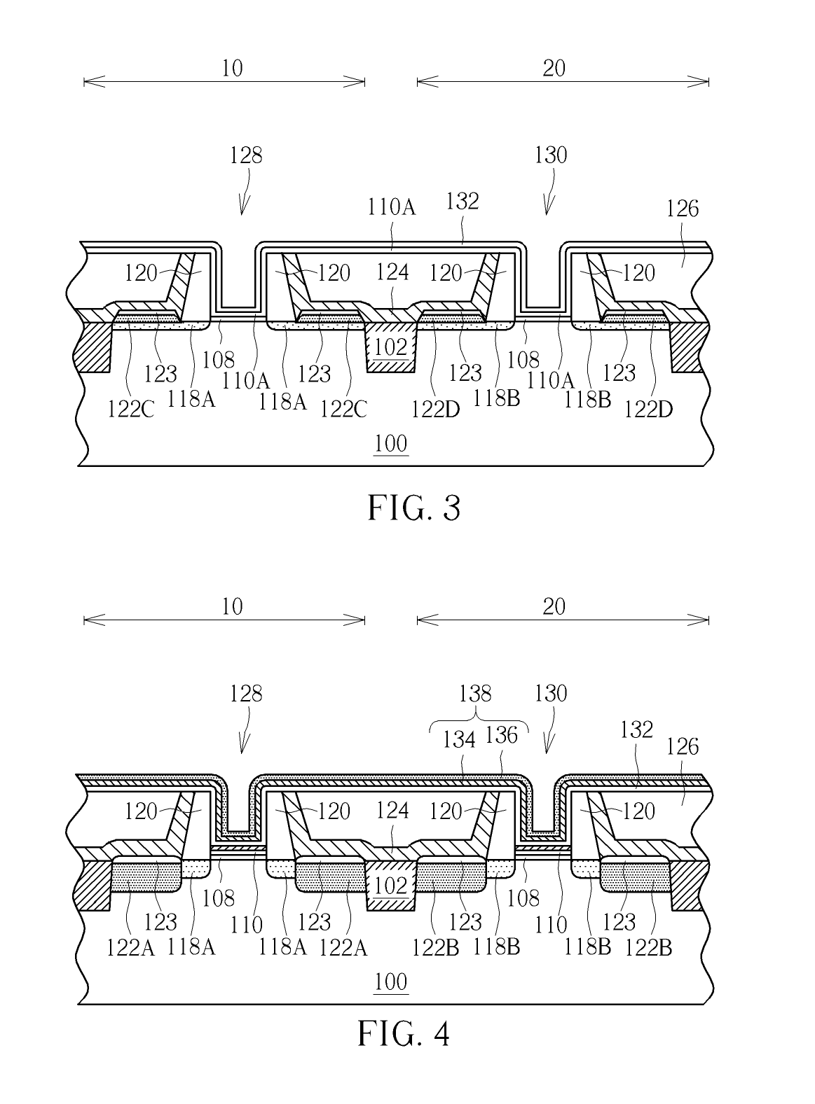

In another exemplary embodiment, as shown in FIG. 3, the gate dielectric layer 110A is formed by a “high-k last” process (that is, the gate dielectric layer is formed after the dummy gate) and its cross section therefore has a “U” shape, which is different from the “-” shaped gate dielectric layer 110 of the embodiment as shown in FIG. 2, which was formed by a “high-k first” process (that is, the gate dielectric layer is formed after removing the dummy gate). In this exemplary embodiment, the previously formed first stack structure and the previously formed second stack structure may not include the gate dielectric layer and the bottom barrier layer. Furthermore, the interfacial layer 108 can be optionally removed after removing the sacrificial gate 114 until exposing the interfacial layer 108 and before forming the gate dielectric layer 110A and the etch stop layer 132.

In other aspects, the first source/drain region 122A and the second source/drain region 122B may include doped source/drain regions formed through ion implantation processes or doped epitaxial layer growth processes, and the shapes of the first source/drain region 122A and the second source/drain region 122B can be modified according to the stress which is predetermined to be induced to the channel region under the later formed metal gate structures. In addition, each component of the semiconductor devices can have different embodiments according to different designs of the semiconductor devices. For example, the source/drain regions can include an epitaxial layer formed by a selective epitaxial growth (SEG) process, wherein the epitaxial layer can be directly formed on the semiconductor substrate 100 such as the first source/drain region 122C and the second source/drain region 122D shown in FIG. 3, or recesses are previously formed at two sides of the first stack structure 104/the second stack structure 106 and an epitaxial layer is further formed to fill the recesses such as the first source/drain region 122A and the second source/drain region 122B shown in FIG. 2, in order to induce stress to the channel region underneath the gate structure 108. In this exemplary embodiment, when the first region 10 serves as a PMOS region and the second region 20 serves as a PMOS region, the epitaxial layer in the first source/drain region 122A/122C can be made of SiGe to provide compressive stress to the channel region, while the epitaxial layer in the second source/drain region 122B/122D can be made of SiP or SiC to provide tensile stress to the channel region, but is not limited thereto. Additionally, a dry etching process, a wet etching process or a combination thereof can be performed to form the recesses with various types of shapes, such as a barrel shaped recess, a hexagonal recess or an octagonal recess. Therefore, the epitaxial layer later formed in such recesses may have a hexagonal (also called “sigma Σ”) or an octagonal cross section, and a substantially flat bottom surface of the epitaxial layer to further enhance the stress effect on the channel region. The embodiments illustrated above are only shown for example. The metal gate structure in the present invention can have a variety of embodiments, which are not described for the sake of simplicity. The following description is based on the embodiment shown in FIG. 2.

As shown in FIG. 4, an atomic layer deposition (ALD) process or another proper deposition process is performed to sequentially form a crystalline P-type work function layer such as a P-type work function layer without silicon 134 and an amorphous P-type work function layer such as a silicon-containing P-type work function layer 136 to conformally cover the ILD layer 126 and the bottoms and the inner surfaces of the first gate trench 128 and the second gate trench 130, therefore, to form a multi-layered P-type work function layer 138 on the on the gate dielectric layer 110 in the first gate trench 128 and the second gate trench 130. A material of the P-type work function layer without silicon 134 can be selected from metal materials having a work function ranging between 4.8 eV and 5.2 eV, which may include titanium nitride (TiN), tantalum nitride (TaN), tantalum carbide (TaC), but it is not limited thereto. The material of the P-type work function layer without silicon 134 is preferably different form the material of the neighboring etch stop layer 132 or the material of the bottom barrier layer 112. A composition of the silicon-containing P-type work function layer 136 compared to a composition of the P-type work function layer without silicon 134 further includes silicon atoms, for example, when the P-type work function layer without silicon includes titanium (Ti) atoms and nitrogen (N) atoms, the silicon-containing P-type work function layer would include includes titanium (Ti) atoms, nitrogen (N) atoms and silicon (Si) atoms. An atomic composition ratio of the silicon-containing P-type work function layer 136 includes a silicon ratio between 6% and 20%. Moreover, a density of the silicon-containing P-type work function layer 136 is preferably substantially larger than a density of the P-type work function layer without silicon 134. In this exemplary embodiment, the material of the crystalline P-type work function layer without silicon 134 could be titanium nitride (TiN) with a density 4.6˜5.2 g/cm³, and a material of the amorphous silicon-containing P-type work function layer 136 could be titanium silicon nitride (TiSiN) with a density 4.0˜5.4 g/cm³.

It is appreciated that, the ALD process used for forming the P-type work function layer without silicon 134 includes providing a titanium precursor and an nitrogen precursor to the semiconductor substrate 100 to form titanium nitride (TiN) layer, while the ALD process used for forming the silicon-containing P-type work function layer 136 includes providing a titanium precursor and an nitrogen precursor to the semiconductor substrate 100 before providing a silicon precursor to the semiconductor substrate 100. More specifically, a titanium nitride (TiN) is firstly formed, and the silicon atom is later added to react with TiN layer to form silicon-nitrogen (Si—N) bonds; therefore, the TiN layer having a regular grain boundary can be changed into a titanium silicon nitride (TiSiN) layer without regular grain boundary. In another exemplary embodiment, the order of providing precursors in the ALD process used for forming the silicon-containing P-type work function layer 136 can be adjusted to provide a titanium precursor before providing a nitrogen precursor and a silicon precursor. In this way, a titanium layer is firstly formed, and the later formed silicon-nitrogen (Si—N) bonds may react with the titanium layer to form TiSiN layer. Additionally, in the interval of the adsorption process for providing precursors, purge processes for providing cleaning gases can be performed. Furthermore, the above processes may further include a thermal process and/or a plasma process in order to increase the reactivity rate. In this exemplary embodiment, the titanium precursor includes titanium tetrachloride (TiCl₄), the nitrogen precursor includes ammonia (NH₃), and the silicon precursor includes silane (SiH₄), but is not limited thereto.

The method of forming the silicon-containing P-type work function layer 136 is not limited as illustrated above. In other exemplary embodiment, the method of forming the silicon-containing P-type work function layer 136 includes the following steps. At first, a deposition process is performed to form a titanium nitride (TiN) layer. Then, a physical vapor deposition (PVD) process is performed to form a silicon layer covering the TiN layer. Finally, a thermal process is performed to make the silicon atom diffuse into the TiN layer, and a titanium silicon nitride (TiSiN) layer can be formed.

Moreover, the present invention is not limited to respectively form the P-type work function layer without silicon 134 and the silicon-containing P-type work function layer 136 through different processes. In an exemplary embodiment, a P-type work function layer without silicon such as a titanium nitride (TiN) layer having a thickness close to a predetermined thickness of the multi-layered P-type work function layer 138 is firstly formed, and silicon atoms are subsequently introduced to react with the P-type work function layer without silicon, accordingly, a part of the P-type work function layer without silicon can be changed to the silicon-containing P-type work function layer, therefore, the P-type work function layer without silicon 134 and the silicon-containing P-type work function layer 136 can be simultaneously formed in the same reaction chamber (i.e. formed through in-situ reaction).

The multi-layered P-type work function layer 138 is not limited to include one P-type work function layer without silicon 134 and one silicon-containing P-type work function layer 136. The illustrated method of forming the P-type work function layer without silicon 134 and the illustrated method of forming the silicon-containing P-type work function layer 136 can be alternately performed; therefore, the multi-layered P-type work function layer can include a stack composed of multi P-type work function layers without silicon and multi silicon-containing P-type work function layers. The number and the arrangement of the P-type work function layer without silicon and the silicon-containing P-type work function layer. i.e. the crystalline P-type work function layer and the amorphous P-type work function layer, in the multi-layered P-type work function layer can be modified according to the process requirements. It is appreciated that, a top layer of the multi-layered P-type work function layer is preferably an amorphous P-type work function layer such as a silicon-containing P-type work function layer, and a bottom layer of the multi-layered P-type work function layer may be a crystalline P-type work function layer such as a P-type work function layer without silicon or an amorphous P-type work function layer such as a silicon-containing P-type work function layer. In one exemplary embodiment, an amorphous P-type work function layer can also be formed before forming a crystalline P-type work function layer. In other words, an amorphous first silicon-containing P-type work function layer (as a first P-type work function layer) is firstly formed, and a crystalline P-type work function layer without silicon (as a second P-type work function layer) and an amorphous silicon-containing P-type work function layer (as a third P-type work function layer) are later formed in sequence on the first P-type work function layer.

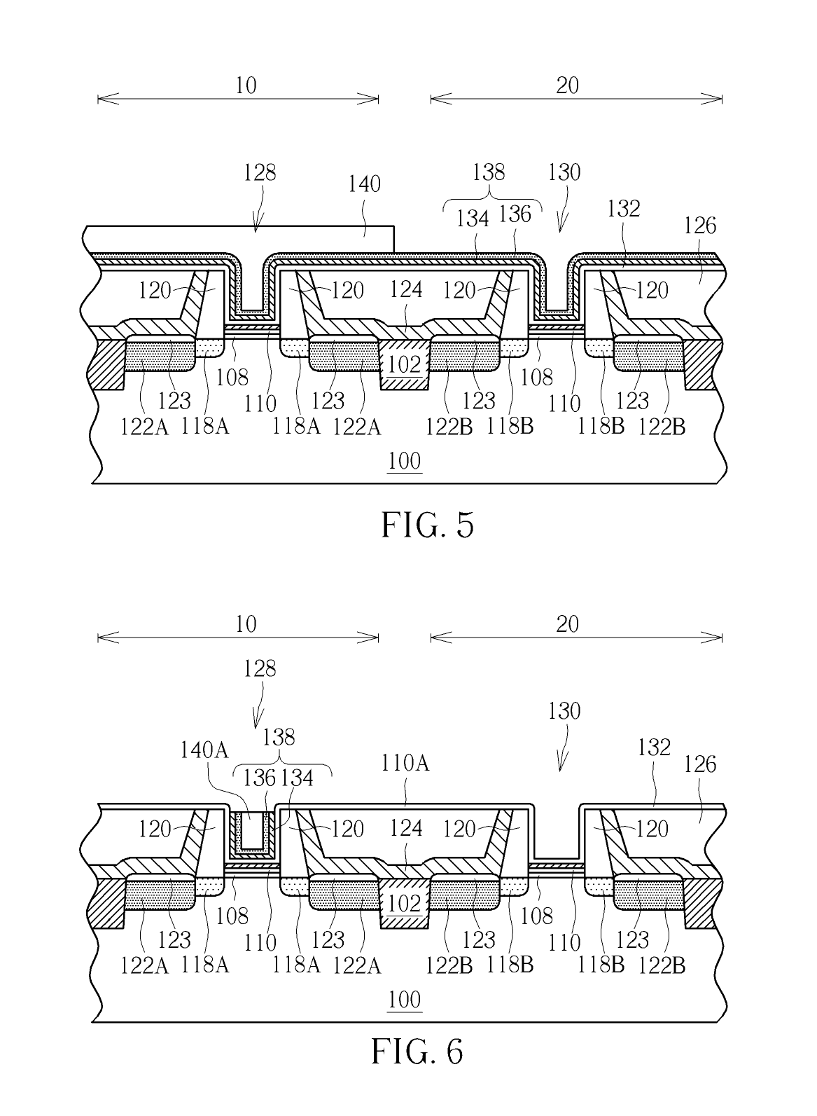

As shown in FIG. 5, a photolithographic process is carried out to form a single-layered or a multi-layered patterned photoresist layer 140 on the substrate 100. The patterned photoresist layer 140 can expose the multi-layered P-type work function layer 138 in the second region 20. Then, a suitable etchant is used to remove the multi-layered P-type work function layer 138 not covered by the patterned photoresist layer 140 to expose the etch stop layer 132 in the second gate trench 130. During the process of removing the multi-layered P-type work function layer 138, the etch stop layer 132 is used to prevent the underneath bottom barrier layer 112 and the gate dielectric layer 110 from being removed.

As shown in FIG. 6, in another exemplary embodiment, the patterned photoresist layer 140A can be only formed in the first gate trench 128, and the surface of the patterned photoresist layer 140A is lower than the opening of the first gate trench 128 without overlapping the ILD layer 126 at two sides of the first gate trench 128. Accordingly, during the subsequent etching processes for removing the multi-layered P-type work function layer 138 in the second region 20, the multi-layered P-type work function layer 138 near the opening of the first gate trench 128 can also be trimmed or removed concurrently, and the inner surface of the first gate trench 128 near the opening can be exposed; therefore, the opening of the first gate trench 128 is enlarged and the gap-filling result of the following formed conductive metal layer in the first gate trench 128 can be improved.

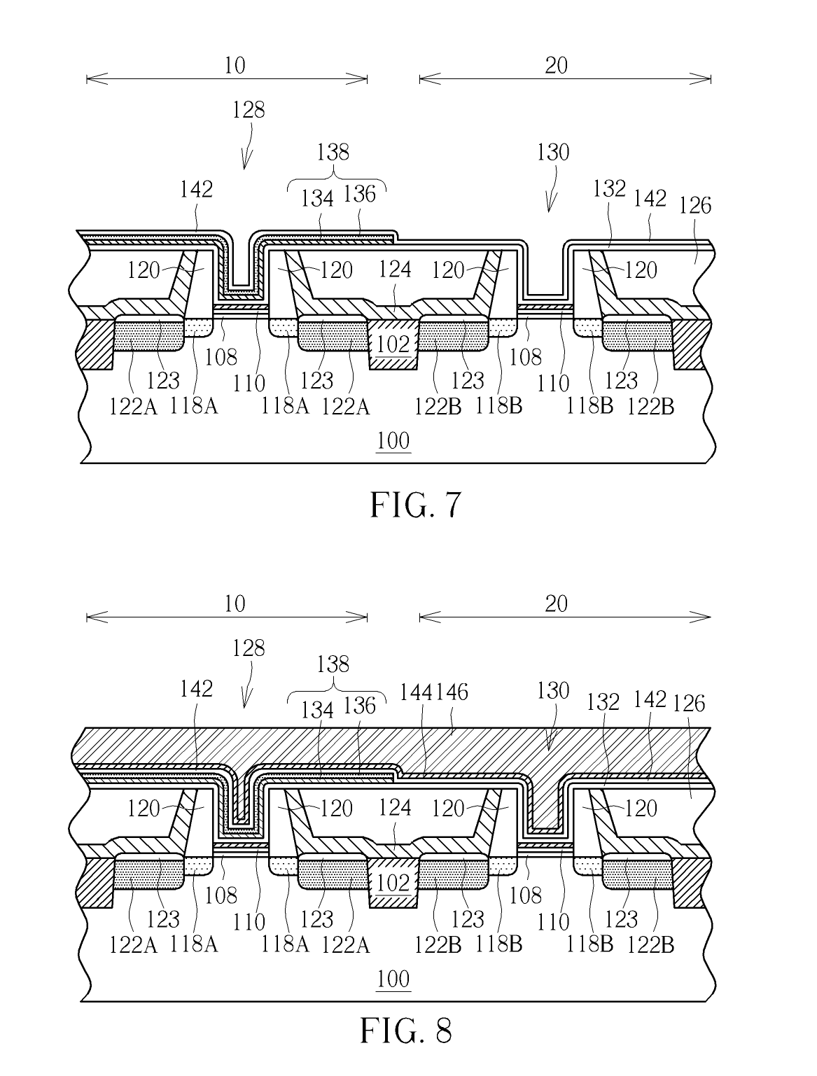

As shown in FIG. 7, after removing the patterned photoresist layer 140, a deposition process such as a chemical vapor deposition (CVD) process or a physical vapor deposition (PVD) process is performed to overall form an N-type work function layer 142 on the semiconductor substrate 100, and the N-type work function layer 142 in the first region 10 covers the multi-layered P-type work function layer 138. A material of the N-type work function layer 142 can be selected from metal materials having a work function ranging between 3.9 eV and 4.3 eV, which may include titanium aluminide (TiAl), zirconium aluminide (ZrAl), tungsten aluminide (WAl), tantalum aluminide (TaAl), or hafnium aluminide (HfAl), but it is not limited thereto. The N-type work function layer 142 may have a single-layered or a multi-layered structure. In this exemplary embodiment, the N-type work function layer 142 is a TiAl layer.

As shown in FIG. 8, a conductive metal layer 146 is formed on the N-type work function layer 142 to fill with the first gate trench 128 and the second gate trench 130. Before forming the conductive metal layer 146, a top barrier layer 144 can be selectively formed. A material of the top barrier layer 144 may include titanium nitride (TiN) or tantalum nitride (TaN), but is not limited thereto. The disposition of the top barrier layer 144 can improve the adhesivity and the filling ability of the conductive metal layer 146, or to prevent the atoms in the conductive metal layer 146 from penetrating through the underneath work function layers, i.e. to prevent the electro-migration or the thermal diffusion of the atoms. The conductive metal layer 146 may be selected from metals or metal oxides with superior filling ability and/or low resistance, such as copper (Cu), aluminum (Al), tungsten (W), titanium aluminum (TiAl), titanium aluminum oxide (TiAlO), cobalt tungsten phosphide (CoWP) or any combination thereof, but is not limited thereto.

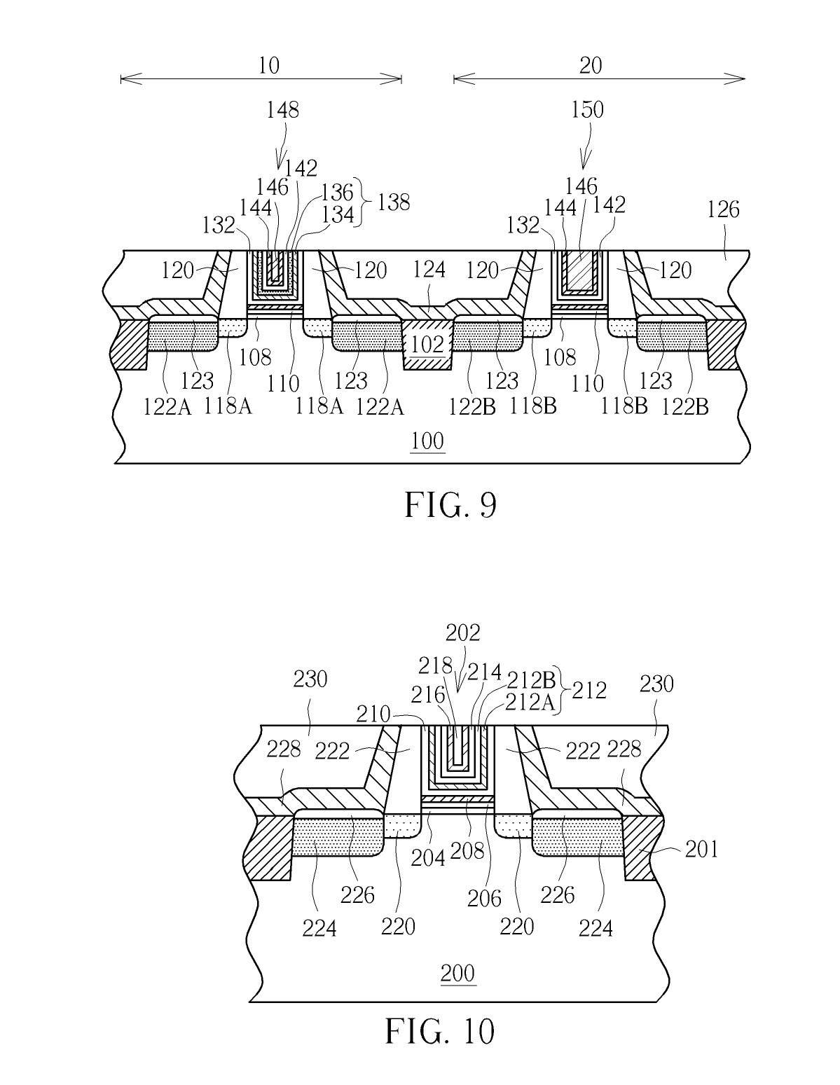

As shown in FIG. 9, a planarization process, such as a chemical mechanical polish (CMP) process or an etching back process, is performed to remove the conductive metal layer 146, the top barrier layer 144, the N-type work function layer 142, the multi-layered P-type work function layer 138 and the etch stop layer 132 outside the first gate trench 128 and the second gate trench 130, until the ILD layer 126 is exposed. Accordingly, the first metal gate structure 148 in the first region 10 and the second metal gate structure 150 in the second region 20 are completed.

The present invention also provides a metal gate structure including a multi-layered P-type work function layer. Please refer to FIG. 10, which illustrates a metal gate structure according to a preferred exemplary embodiment of the present invention. As shown in FIG. 10, a metal gate structure 202 is disposed on a semiconductor substrate 200, and is preferably disposed in the PMOS region of the semiconductor substrate 200, furthermore, a plurality of shallow trench isolations (STI) 201 are disposed in the semiconductor substrate 200 to provide electrically isolation effect. The metal gate structure 202 includes an interfacial layer 204, a gate dielectric layer 206, a bottom barrier layer 208, an etch stop layer 210, a multi-layered P-type work function layer 212, a N-type work function layer 214, a top barrier layer 216 and a conductive metal layer 218 sequentially disposed on the semiconductor substrate 200. The metal gate structure 202 further includes a lightly doped drain 220 and a source/drain region 224, wherein the source/drain region 224 may include an epitaxial layer to provide stress to the channel region under the metal gate structure 202. A metal silicide layer 226 can be selectively disposed on the source/drain region 224 to reduce the electrical resistance between the later formed contact plug and the source/drain region 224. Furthermore, the metal gate structure 202 is surrounded by a spacer 222, a contact etch stop layer (CESL) 228 and an inter-layer dielectric (ILD) layer 230.

It is appreciated that, the multi-layered P-type work function layer 212 includes at least a crystalline P-type work function layer and at least an amorphous P-type work function layer, for example, at least a crystalline P-type work function layer without silicon 212A and at least an amorphous silicon-containing P-type work function layer 212B, and an atomic composition ratio of the silicon-containing P-type work function layer 212B includes a silicon ratio between 6% and 20%. In this exemplary embodiment, a material of the crystalline P-type work function layer without silicon 212A may include titanium nitride (TiN), and a material of the amorphous silicon-containing P-type work function layer 212B may include titanium silicon nitride (TiSiN). The P-type work function layer without silicon 212A as a crystalline P-type work function layer may include column-shaped channels formed by the regular grain boundary, while the silicon-containing P-type work function layer 212B as an amorphous P-type work function layer does not have regular grain boundary and the column-shaped channels due to the addition of silicon atoms. Accordingly, when the metal atoms such as aluminum (Al) atoms of the N-type work function layer 214 intend to move downward to the multi-layered P-type work function layer 212 during the BEOL thermal processes, the metal atoms can not penetrate through the silicon-containing P-type work function layer 212B. That is, the metal atoms can be stopped by the amorphous P-type work function layer, and the unexpected occurrence of metal atom diffusion can be avoided. In order to achieve this illustrated effect, a thickness of the amorphous P-type work function layer (i.e. the silicon-containing P-type work function layer 212B) to a thickness of the multi-layered P-type work function layer 212 is substantially larger than 1/10. In this exemplary embodiment, a thickness of the silicon-containing P-type work function layer 212B is substantially between 10 and 70 Angstroms (Å), and a thickness of the multi-layered P-type work function layer 212 is substantially between 30 and 100 Angstroms (Å). In other words, the thickness of the silicon-containing P-type work function layer 212B is not limited to be larger than, equal to or smaller than a thickness of the P-type work function layer without silicon 212A, but needs to be substantially larger than 1/10 of the thickness of the multi-layered P-type work function layer 212. Moreover, at least an amorphous silicon-containing P-type work function layer 212B is preferably disposed neighboring the N-type work function layer 214, and the crystalline P-type work function layer without silicon 212A preferably does not contact the N-type work function layer 214.

The multi-layered P-type work function layer is not limited to have a double-layered structure including a single P-type work function layer without silicon and a single silicon-containing P-type work function layer. In other exemplary embodiments, the multi-layered P-type work function layer may include P-type work function layer without silicon—silicon-containing P-type work function layer, or silicon-containing P-type work function layer—P-type work function layer without silicon—silicon-containing P-type work function layer, to be stacked in sequence or be repeatedly stacked in sequence on the semiconductor substrate. In other words, the multi-layered P-type work function layer may include crystalline P-type work function layer—amorphous P-type work function layer, or amorphous P-type work function layer—crystalline P-type work function layer—amorphous P-type work function layer, to be stacked in sequence or be repeatedly stacked in sequence.

In conclusion, the multi-layered P-type work function layer includes an amorphous silicon-containing P-type work function layer disposed on a crystalline P-type work function layer without silicon. The silicon-containing P-type work function layer does not include regular grain boundary; therefore, the amorphous silicon-containing P-type work function layer can be used to prevent the metal atoms from the N-type work function layer or the conductive metal layer from diffusing into the P-type work function layers during the later thermal processes. Accordingly, shifts of the work function value of the metal gate can be avoided, and the predetermined performances of the semiconductor device can be obtained.

Those skilled in the art will readily observe that numerous modifications and alterations of the device and method may be made while retaining the teachings of the invention. Accordingly, the above disclosure should be construed as limited only by the metes and bounds of the appended claims.

1. A metal gate structure, comprising:
a gate dielectric layer disposed on a semiconductor substrate;
a multi-layered P-type work function layer disposed on the gate dielectric layer, wherein the multi-layered P-type work function layer comprises at least a crystalline P-type work function layer and at least an amorphous P-type work function layer; and
a conductive metal layer disposed on the multi-layered P-type work function layer.

2. The metal gate structure according to claim 1, further comprising an N-type work function layer disposed between the multi-layered P-type work function layer and the conductive metal layer, wherein a material of the N-type work function layer comprises aluminum (Al).

3. The metal gate structure according to claim 1, wherein the crystalline P-type work function layer comprises a P-type work function layer without silicon and the amorphous P-type work function layer comprises a silicon-containing P-type work function layer.

4. The metal gate structure according to claim 3, wherein a density of the silicon-containing P-type work function layer is substantially larger than a density of the P-type work function layer without silicon.

5. The metal gate structure according to claim 3, wherein an atomic composition ratio of the silicon-containing P-type work function layer comprises a silicon ratio between 6% and 20%.

6. The metal gate structure according to claim 3, wherein a ratio of a thickness of the silicon-containing P-type work function layer to a thickness of the multi-layered P-type work function layer is substantially larger than 1/10.

7. The metal gate structure according to claim 3, wherein a thickness of the silicon-containing P-type work function layer is substantially between 10 and 70 Angstroms (Å), and a thickness of the multi-layered P-type work function layer is substantially between 30 and 100 Angstroms.

8. The metal gate structure according to claim 1, wherein a ratio of a thickness of the amorphous P-type work function layer to a thickness of the multi-layered P-type work function layer is substantially larger than 1/10.

9. The metal gate structure according to claim 1, wherein a material of the crystalline P-type work function layer comprises titanium nitride (TiN), and a material of the amorphous P-type work function layer comprises titanium silicon nitride (TiSiN).

10. The metal gate structure according to claim 1, further comprising a bottom barrier layer disposed between the gate dielectric layer and the multi-layered P-type work function layer.

11. A method of fabricating a metal gate structure, comprising:
forming an inter-layer dielectric (ILD) layer on a substrate;
forming a gate trench in the ILD layer;
forming a gate dielectric layer in the gate trench;
forming a multi-layered P-type work function layer on the gate dielectric layer, wherein a method of forming the multi-layered P-type work function layer at least comprises a step of forming an amorphous P-type work function layer after a step of forming a crystalline P-type work function layer; and
forming a conductive metal layer to fill with the gate trench.

12. The method of fabricating a metal gate structure according to claim 11, wherein the step of forming the amorphous P-type work function layer comprises performing an atomic layer deposition (ALD) process.

13. The method of fabricating a metal gate structure according to claim 12, wherein the ALD process comprises providing a titanium precursor and a nitrogen precursor before providing a silicon precursor.

14. The method of fabricating a metal gate structure according to claim 12, wherein the ALD process comprises providing a titanium precursor before providing a nitrogen precursor and a silicon precursor.

15. The method of fabricating a metal gate structure according to claim 11, wherein the step of forming the amorphous P-type work function layer comprises:
forming a titanium nitride (TiN) layer;
forming a silicon layer covering the TiN layer; and
performing a thermal process.

16. The method of fabricating a metal gate structure according to claim 11, further comprising:
forming a bottom barrier layer on the gate dielectric layer before forming the multi-layered P-type work function layer.

17. The method of fabricating a metal gate structure according to claim 11, further comprising:
forming an amorphous first P-type work function layer before forming the crystalline P-type work function layer.

18. The method of fabricating a metal gate structure according to claim 11, further comprising:
forming an N-type work function layer on the multi-layered P-type work function layer.

19. The method of fabricating a metal gate structure according to claim 11, wherein the step of forming the crystalline P-type work function layer comprises forming a P-type work function layer without silicon, and the step of forming the amorphous P-type work function layer comprises forming a silicon-containing P-type work function layer.

20. The method of fabricating a metal gate structure according to claim 11, wherein the amorphous P-type work function layer comprises a silicon-containing P-type work function layer, and an atomic composition ratio of the silicon-containing P-type work function layer comprises a silicon ratio between 6% and 20%.
